(19) United States
(12) Patent Application Publication
(10) Pub. No.: US 2023/0080214 A1
(43) Pub. Date: Mar. 16, 2023

(54) SYSTEM AND METHOD FOR ANALYSIS OF INTEGRATED CIRCUIT TESTING ANOMALIES BASED ON DEEP LEARNING

(71) Applicant: SINO IC TECHNOLOGY CO., LTD., Shanghai (CN)

(72) Inventors: Kun YU, Shanghai (CN); Zhiyong ZHANG, Shanghai (CN); Jianhua QI, Shanghai (CN); Yi WU, Shanghai (CN); Yongjia WU, Shanghai (CN); Yong NIU, Shanghai (CN)

(21) Appl. No.: 17/796,376

(22) PCT Filed: Aug. 31, 2021
(86) PCT No.: PCT/CN2021/115518

§ 371 Date: Jul. 29, 2022

(30) Foreign Application Priority Data
Jul. 15, 2021 (CN) 202110801261.3

(51) Int. Cl. G01R 31/28; G06N 3/08; G06N 3/04

(52) U.S. Cl. CPC G01R 31/2851; G06N 3/04; G06N 3/08

(57) ABSTRACT

The present invention provides a system and method for analysis of integrated circuit testing anomalies based on deep learning. Through repeated training by deep learning with historical test data accumulated during testing, automatic optimization of parameter settings depending on learning and training conditions is made possible. Moreover, based on real-time test data, testing anomalies can be predicted and early warnings against them can be provided to allow advanced intervention for preventing their occurrence. Additionally, for testing anomalies that have occurred, solutions can be automatically identified and provided, which shorten the times taken by different technicians to address the anomalies, resulting in more effective utilization of the equipment and lower testing cost.

### TECHNICAL FIELD

The present invention relates to the field of integrated circuit (IC) testing technology and testing hardware and, more specifically, to a system and method for analysis of IC testing anomalies based on deep learning.

### BACKGROUND

Integrated circuit (IC) testing is a process for testing an IC or a module to determine or assess the functionality and performance of components therein, which involves applying a stimulus to the IC and comparing an output response of the IC with an expected output. It is an important means to verify design, fabrication, packaging and other parts of IC production and to ensure quality of the produced ICs. The development of an IC test mainly includes the design of testing hardware and the development of testing programs. The developed test is then verified in terms of testing environment, hardware, programs and the like. Subsequent to the verification, hardening is done, and automatic testing equipment (ATE) for ICs, mechanical handlers for testing of final IC products, a probe station for IC wafer testing and other equipment are deployed to enable automated mass testing of ICs with improved production and testing efficiency.

Testing anomalies are inevitable during testing, such as hardware anomalies, software anomalies and yield anomalies. Hardware anomalies include, among others, test socket anomalies, test probe card anomalies and test load board anomalies. Software anomalies include, among others, testing program anomalies and anomalies in the invocation of testing configurations. Yield anomalies include low total test yields, significant site-to-site test yield discrepancies and other anomalies. These anomalies may disable normal mass testing, and many of them cannot be readily identified in an early stage. Consequently, the production has to be interrupted once such anomalies are identified, in order to allow intervention of production technicians for troubleshooting and resumption of mass testing. However, the technicians’ experience and competence directly determine the times taken to address the anomalies and resume mass testing and are directly related to testing outcomes.

### SUMMARY OF THE INVENTION

It is an object of the present invention to provide a system and method for analysis of IC testing anomalies based on deep learning, which are able to predict IC testing anomalies and provide early warnings against them, thus enabling advanced intervention. They are also able to provide solutions to testing anomalies, which shorten the times taken to address these testing anomalies, thereby resulting in more effective utilization of the entire equipment and lower testing cost.

To this end, the present invention provides a method for analysis of IC testing anomalies based on deep learning, which includes the steps of:
(S1) collecting test data at a data collection module, wherein the test data comprises historical test data and real-time test data,
(S2) performing format conversion and feature extraction on the historical test data at a first input layer and pre-processing on the real-time test data at a pre-processing sub-module,
(S3) by a neural network sub-module, developing a trained neural network through training the neural network by means of deep learning with the historical test data that have been subject to the feature extraction and inputting the pre-processed real-time test data to the trained neural network for computational processing for deriving early warning information about testing anomalies and solutions to testing anomalies that have occurred,
(S4) at a human-computer interaction module, receiving the early warning information about testing anomalies and the solutions to testing anomalies that have occurred and displaying early warnings against the testing anomalies and the solutions.

Optionally, S3 may include:
(S31) at a second input layer in the neural network sub-module, receiving the historical test data that have been subject to the feature extraction, transmitting the received data to a middle layer in the neural network sub-module, and receiving the pre-processed real-time test data from the pre-processing sub-module;
(S32) by the middle layer, developing the trained neural network through training the neural network by means of deep learning with the historical test data that have been subject to the feature extraction, inputting the pre-processed real-time test data to the trained neural network for computational processing for deriving, in an event of anomalous testing, early warning information about testing anomalies and solutions to testing anomalies that have occurred, and transmitting the early warning information and the solutions to an output layer in the neural network sub-module; and
(S33) at the output layer, receiving the early warning information about testing anomalies and the solutions to testing anomalies that have occurred output from the middle layer and transmitting the early warning information and the solutions to the human-computer interaction module.

Additionally, an output data yI of the middle layer obtained from learning by the neural network may satisfy a following formula:

$$y 1 = \text{F} \left(\text{x,} \left\{{W}_{i}\right\}\right) ,$$

where x represents the historical test data input to the middle layer and Wᵢ denotes an i-th layer in the network.

Additionally, the output yI of the middle layer obtained from learning by the neural network serving as a two-layer network may be

$$\text{y1=} σ \left({\text{W}}_{2} σ \left({\text{W}}_{1} \text{x}\right)\right) ,$$

where σ is a nonlinear activation function.

Additionally, through the training by deep learning in the middle layer, a cross-entropy loss function corresponding to a minimized error may be

$${\text{L}}_{log} \left(\text{y,} \text{p}\right) = - \left(\text{y log} \left(\text{p}\right) + \left(1 - \text{y}\right) \text{log} \left(1 - \text{p}\right)\right)$$

where y is a classification label having a value of 0 or 1, p is a probability of normal testing, and 1-p is a probability of anomalous testing.

Optionally, the solutions may comprise: how to achieve testing optimization; reminders for calibration or maintenance of testers, test probe cards and test fixtures; and automatic identification of testing anomalies that have occurred.

Optionally, the feature extraction may include classification of each type of neurons as normal or anomalous.

In another aspect, the present invention provides a system for analysis of IC testing anomalies based on deep learning for implementing the method for analysis of IC testing anomalies, which includes:
a data collection module, configured to collect test data, wherein the test data comprise historical test data and real-time test data;
a first input layer, configured to perform format conversion and feature extraction on the historical test data;
a pre-processing sub-module, configured to pre-process the real-time test data;
a neural network sub-module, configured to develop a trained neural network through training the neural network by means of deep learning with the historical test data that have been subject to the feature extraction and input the pre-processed real-time test data to the trained neural network for computational processing for deriving early warning information about testing anomalies and solutions to testing anomalies that have occurred, and
a human-computer interaction module, configured to receive the early warning information about testing anomalies and the solutions to testing anomalies that have occurred and displaying early warnings against the testing anomalies and the solutions.

Optionally, the test data may include testing equipment data, testing hardware data, test yield data, test result data, test process data and test time data.

Optionally, the neural network sub-module may include:
a second input layer, configured to receive the historical test data that have been processed by the first input layer and the real-time test data that have been pre-processed by the pre-processing sub-module and transmit the test data to the middle layer;
a middle layer, configured to develop the trained neural network through training the neural network by means of deep learning with the historical test data, input the pre-processed real-time test data to the trained neural network for computational processing for deriving, in an event of anomalous testing, early warning information about testing anomalies and solutions to testing anomalies that have occurred, and transmit the early warning information about testing anomalies and the solutions to testing anomalies that have occurred to an output layer; and
the output layer, configured to transmit the early warning information about testing anomalies and the solutions to testing anomalies that have occurred to the human-computer interaction module.

The present invention provides the following beneficial effects over the prior art:

The present invention provides a system and method for analysis of IC testing anomalies based on deep learning. The method for analysis of IC testing anomalies based on deep learning includes: performing format conversion and feature extraction on historical test data at a first input layer and pre-processing on real-time test data at a pre-processing sub-module; by a neural network sub-module, developing a trained neural network through training the neural network by means of deep learning with the historical test data that have been subject to the feature extraction and inputting the pre-processed real-time test data to the trained neural network for computational processing for deriving early warning information about testing anomalies and solutions to testing anomalies that have occurred. In this way, automatic optimization of parameter settings depending on learning and training conditions is made possible. Moreover, based on the real-time test data, testing anomalies can be predicted and early warnings against them can be provided to allow advanced intervention for preventing their occurrence. Additionally, for testing anomalies that have occurred, solutions can be automatically identified and provided, which shorten the times taken by different technicians to address the anomalies, resulting in more effective utilization of the equipment and lower testing cost.

### BRIEF DESCRIPTION OF THE DRAWINGS

FIG. 1 is a schematic diagram showing the structure of a system for analysis of IC testing anomalies based on deep learning according to an embodiment of the present invention.

FIG. 2 schematically shows test data in the event of a test yield anomaly according to an embodiment of the present invention.

### DESCRIPTION OF REFERENCE NUMERALS IN DRAWINGS

100 - Data Collection Module;

200 - Anomaly Analysis Module; 210 - Pre-processing Sub-Module; 220 - First Input Layer, 230 - Neural Network Sub-module; 231 - Second Input Layer; 232 -Middle Layer; 233 - Output Layer;

300 - Human-Computer Interaction Module.

### DETAILED DESCRIPTION

A system and method for analysis of IC testing anomalies based on deep learning according to the present invention will be described in greater detail below. The present invention will be described in greater detail below with reference to the accompanying drawings, which present preferred embodiments of the invention. It would be appreciated that those skilled in the art can make changes to the invention disclosed herein while still obtaining the beneficial results thereof. Therefore, the following description shall be construed as being intended to be widely known by those skilled in the art rather than as limiting the invention.

For the sake of clarity, not all features of an actual implementation are described in this specification. In the following, description and details of well-known functions and structures are omitted to avoid unnecessarily obscuring the invention. It should be appreciated that in the development of any such actual implementation, numerous implementation-specific decisions must be made to achieve specific goals of the developers, such as compliance with system-related and business-related constrains, which may vary from one implementation to another. Moreover, it should be appreciated that such a development effort might be complex and time consuming, but would nevertheless be a routine undertaking for those of ordinary skill in the art.

Objects and features of the present invention will become more apparent upon reading the following more detailed description thereof made with reference to the accompanying drawings and particular embodiments. Note that the figures are provided in a very simplified form not necessarily drawn to exact scale and for the only purpose of facilitating easy and clear description of the disclosed embodiment.

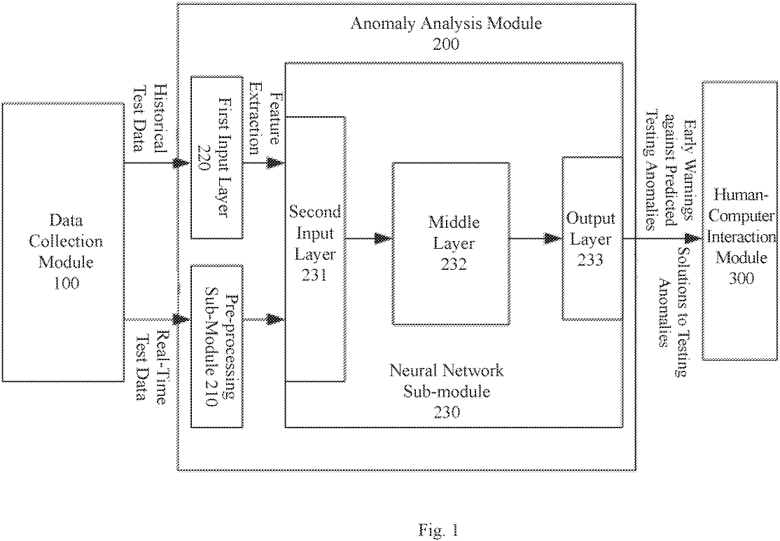

In embodiments of the present invention, there is provided a system for analysis of IC testing anomalies based on deep learning. FIG. 1 is a schematic diagram showing the structure of the system for analysis of IC testing anomalies based on deep learning according to an embodiment of the present invention. As shown in FIG. 1, the system for analysis of IC testing anomalies includes a data collection module 100, an anomaly analysis module 200 and a human-computer interaction module 300.

The data collection module 100 is adapted to collect test data. The test data include historical test data and real-time test data.

The test data include, but are not limited to, testing equipment data, testing hardware data, test yield data, test result data, test process data, test time data, etc. In particular, the testing equipment data may include interface requirements, configurations, calibration data, temperature settings and other data of testing devices such as testers on pilot lines, probe stations and mechanical handlers. The testing hardware data may include data about lifespans and conditions of testing hardware such as test load boards, test probe cards and test fixtures. The test yield data may include yield requirements for products under test, distributions of the products’ key parameters, yield requirements relating to the products’ key parameters, test yields of historical batches, initial test yields, retest rates, recovery rates, site-to-site differences, etc. The test result data may include X coordinates, Y coordinates, bin numbers, test limits for individual parameters, detailed test data, etc. Possible formats of the test result data txt, stdf, xml, etc. The test process data may include test orders, test process cards, test site information, etc. The test time data may include initial test times, retest times, pause times, etc. The historical test data include normal test data, anomalous test data and countermeasures against anomalies.

The anomaly analysis module 200 includes a pre-processing sub-module 210, a first input layer 220 and a neural network sub-module 230.

The pre-processing sub-module 210 is adapted to receive and pre-process the real-time test data. The pre-processing involves, for example, extracting information from the real-time test data and converting the real-time test data into a unified format. After that, it transmits the pre-processed real-time test data to the neural network sub-module 230. The historical test data are taken as neurons in the first input layer 220, and the real-time test data as neurons in the second input layer.

The first input layer 220 is adapted to receive the historical test data and convert formats of data, text, images and the like in the multi-modal historical test data, which are different. For example, probe mark images of the test probe cards, test maps and other historical image information are converted to floating-point data. In this way, the neural network sub-module 230 can integrate the data, text, images and the like of different formats. It is also adapted to perform feature extraction (i.e., classification) on the historical test data to identify correlation between the various types of test data and label each type of neurons (e.g., as “normal” or “anomalous”).

The neural network sub-module 230 is adapted to receive the real-time test data processed by the pre-processing sub-module 210 and the historical test data processed by the first input layer 220, develop a trained neural network through training the neural network with the historical test data by means of deep learning, and input the pre-processed real-time test data to the trained neural network for computational processing for deriving, in the event of anomalous testing, early warning information about testing anomalies and solutions to testing anomalies that have occurred, and output the early warning information about testing anomalies and the solutions to testing anomalies that have occurred.

The neural network sub-module 230 includes a second input layer 231, a middle layer 232 and an output layer 233.

The second input layer 231 is adapted to receive the historical test data processed by the first input layer 220 and the real-time test data pre-processed by the pre-processing sub-module 210 and transmit the test data to the middle layer 232. At this point, the pre-processed real-time test data are taken as neurons in the second input layer 231.

The middle layer 232 is adapted to develop the trained neural network by training the neural network with the historical test data by means of deep learning and input the pre-processed real-time test data to the trained neural network for computational processing for deriving, in the event of anomalous testing, early warning information about testing anomalies and solutions to testing anomalies that have occurred, and transmit the early warning information about testing anomalies and the solutions to testing anomalies that have occurred to the output layer 233. Through repeated deep learning-based training, the middle layer 232 is able to predict IC testing anomalies and provide early warnings against them and automatically identify solutions to testing anomalies, which shorten the times taken by different technicians to address these testing anomalies, thereby resulting in more effective utilization of the entire equipment and lower testing cost.

The output layer 233 is adapted to transmit the early warning information about testing anomalies and the solutions to testing anomalies that have occurred to the human-computer interaction module 300.

The human-computer interaction module 300 is adapted to provide early warnings against the testing anomalies based on the early warning information and display the solutions to the testing anomalies.

In embodiments of the present invention, there is also provided a method for analysis of IC testing anomalies based on deep learning by a neural network, which includes the steps as follows.
S1: Collecting test data at a data collection module. The test data include historical test data and real-time test data.
S2: Performing format conversion and feature extraction on the historical test data at a first input layer and pre-processing on the real-time test data at a pre-processing sub-module.
S3: Developing a trained neural network by a neural network sub-module through training the neural network by means of deep learning with the historical test data that have been subject to the feature extraction and inputting the pre-processed real-time test data to the trained neural network for computational processing for deriving early warning information about testing anomalies and solutions to testing anomalies that have occurred.
S4: Receiving the early warning information about testing anomalies and the solutions to testing anomalies that have occurred and displaying early warnings against the testing anomalies and the solutions at a human-computer interaction module

In some embodiments, the method further includes, between steps S3 and S2, at a second input layer in the neural network sub-module, receiving the historical test data that have been subject to the feature extraction, transmitting the data to a middle layer in the neural network sub-module, and receiving the pre-processed real-time test data from the pre-processing sub-module. The method further includes, between steps S3 and S4, at an output layer, receiving the early warning information about testing anomalies and the solutions to testing anomalies that have occurred output from the middle layer and transmitting them to the human-computer interaction module. Specifically, in step S3, the middle layer develops the trained neural network through training the neural network by deep learning with the historical test data that have been subject to the feature extraction, inputs the pre-processed real-time test data to the trained neural network for computational processing for deriving, in the event of anomalous testing, early warning information about testing anomalies and solutions to testing anomalies that have occurred, and transmits them to the output layer.

In some embodiments, step S3 in particular includes:
at first, at the second input layer 231, receiving the historical test data that have been subject to the feature extraction, transmitting the data to the middle layer 232, and receiving the pre-processed real-time test data from the pre-processing sub-module; and
next, developing the trained neural network through training the neural network by deep learning with the historical test data that have been subject to the feature extraction. The trained neural network is developed by the middle layer 232 as detailed below.

First of all, the neural network can obtain, through learning, output data y1 from the middle layer 232, which satisfy the following formula:

$$\text{y} 1 = \text{F} \left(\text{x,} \left\{{W}_{i}\right\}\right) ,$$

where x represents the historical test data input to the middle layer, and Wᵢ denotes an i-th layer in the network.

The output y1 from the middle layer 232 obtained through learning by the neural network in case of it being a two-layer network will be:

$$\text{y1=} σ \left({\text{W}}_{2} σ \left({\text{W}}_{1} \text{x}\right)\right) ,$$

where σ is a nonlinear activation function.

Through training with a large amount of data by deep learning in the middle layer, a network function corresponding to a minimized error (e.g., a cross-entropy loss function) is determined, which is capable of automatic identification of testing anomalies and solutions thereto. The cross-entropy loss function L_{log}(_{y},p) satisfies the following formula:

$${\text{L}}_{\text{log}} \left(\text{y, p}\right) = - \left(\text{y log} \left(\text{p}\right) + \left(1 - \text{y}\right) \text{log} \left(1 - \text{p}\right)\right)$$

where, y is a classification label having a value of 0 or 1, p is a probability of normal testing, and 1-p is a probability of anomalous testing.

The closer I_{log}(y, p) is to 0, the better the neural network is trained. Through training with a large amount of data by deep learning in the middle layer, an optimally trained neural network is obtained.

Next, a large number of real-time test data generated during actual IC testing are pre-processed and processed by the trained neural network in the middle layer 232, deriving early warning information about testing anomalies and solutions to testing anomalies that have occurred. The solutions include: how to achieve testing optimization, for example, by automatic adjustments of probe sharpening settings, retest bin settings and other parameter settings; reminders for calibration or maintenance of, e.g., testers, test probe cards, test fixtures in need thereof; and methods for automatic identification of test process anomalies, test yield anomalies, communication anomalies, test time anomalies and other anomalies.

Subsequent, the output layer 233 receives the early warning information about testing anomalies and the solutions to testing anomalies that have occurred output from the middle layer 232 and transmits them to the human-computer interaction module.

Step S4 includes outputting, at a human-computer interaction interface of a tester (i.e., the human-computer interaction module), indication information based on the early warning information about testing anomalies and the solutions to testing anomalies that have occurred. Using the above-described method, production line technicians can quickly address anomalies, resume mass testing and take other related actions according to the solutions displayed on the human-computer interaction interface.

Taking test probe card condition anomalies as an example, during the testing of each wafer, it is necessary to carry out several probe mark checks at start, intermediate and finish positions on the wafer according to the number of dies on the wafer. In these checks, images are taken, in order to prevent ongoing of the testing with unexpected anomalies in some probe cards (e.g, the absence of probe marks due to burning of power and ground pins), which are not found and remain unaddressed. These test data are collected by the data collection module. A large number of probe mark images are accumulated and input to the first input layer, which then classifies the probe mark images into, e.g., “normal” or “anomalous”. These images are then input to the second input layer and passed thereby on to the middle layer. In the middle layer, a convolutional neural network VGG16 is trained with the historical test data by means of deep learning. Specifically, the convolutional neural network VGG16 is a 16-layer network including 13 convolutional layers and 3 fully connected layers. ReLU activation functions of the convolutional and fully connected layers all satisfy the following formula:

$$R e L U \left(x\right) = m a x \left(0 , x\right)$$

Convolution kernels in each convolutional layer may be sized of 3x3. In the first run, two convolution processes by 64 convolution kernels are followed by one pooling process. In the second run, two convolution processes by 128 convolution kernels, one pooling process, two convolution processes by 256 convolution kernels, one pooling process, two convolution processes by 512 convolution kernels and one pooling process are successively performed. Finally, three full connection processes are performed, resulting in the output y1. After that, an error for determining whether neuron parameters have been optimized is calculated using the following cross-entropy loss function L_{log}(y, p):

$${\text{L}}_{\text{log}} \left(\text{y, p}\right) = - \left(\text{y log} \left(\text{p}\right) + \left(1 - \text{y}\right) \text{log} \left(1 - \text{p}\right)\right) ,$$

where y is a classification label having a value of 0 or 1, p is a probability of normal testing, and 1-p is a probability of anomalous testing.

After repeated training by deep learning, the middle layer receives, from the second input layer, the real-time test data including the probe mark images. Based on the number of times of probe landing and a variation trend seen in successive probe mark images (e.g., with the number of times of probe landing of a certain probe card increasing, probe marks are shown to get closer and closer to an edge), a risk associated with the use of the probe cards is predicted (e.g., a risk of probes on the probe card landing outside pads and thus being damaged). Accordingly, early warning information is output at the human-computer interaction module (i.e., the human-computer interaction interface of the tester), enabling early manual intervention for adjustments in probe landing locations for improved testing quality.

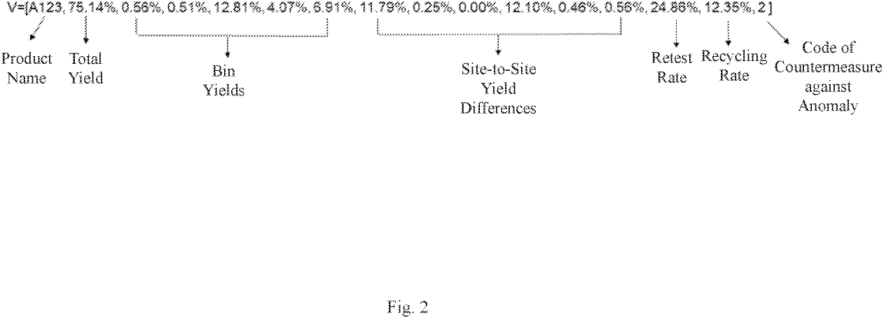

Taking a test yield anomaly as an example, as shown in FIG. 2, during testing, product names, total yields, bin yields, site-to-site yield differences, retest rates, recycling rates, codes of historical countermeasures against yield anomalies and the like are input to the first input layer as one-dimensional vectors V and all converted thereby into floating-point data, which are then input to the second input layer. A deep neural network (DNN) in the middle layer is trained with the historical test data by means of deep learning. Specifically, a sigmoid activation function of the DNN satisfies the following formula:

$$S i g m o i d \left(x\right) = \frac{1}{1 + {e}^{- x}} .$$

This sigmoid activation function can convert a real value within (-∞, +∞) into the interval [0, 1]. An error is then calculated using a cross-entropy loss function. After repeated training by deep learning, a database of three-dimensional vectors defined on X, Y and Z axes which represent “Product Name”, “Anomaly” and “Countermeasure against Anomaly”. During practical testing of an IC product A123, testing at four sites may be performed simultaneously. In the event of a yield anomaly, for example, a yield of the No. 4 bin at the No. 1 site that is lower than a specified value and a site-to-site yield difference exceeding a specified value, the most relevant entry may be automatically retrieved from the database of three-dimensional vectors (“Product Name”, “Anomaly” and “Countermeasure against Anomaly”) and output to the human-computer interaction interface of the tester as indication information for focused handling of test fixtures. With the indication provided by the system, production line technicians can swiftly address the anomaly according to the provided solution, enabling resumption of mass testing.

In summary, the system for analysis of IC testing anomalies based on deep learning according to the present invention can predict testing anomalies, provide early warnings against them and automatically identify solutions to them, through repeatedly training a neural network with a statistical database of accumulated historical testing anomalies by means of deep learning. With the provided solutions, the times taken to address the testing anomaly by different technicians can be shortened, resulting in more effective utilization of the entire equipment and lower testing cost.

It is to be noted that, as used herein, the terms “first”, “second” and the like are only meant to distinguish various components, elements, steps, etc. from each other rather than indicate logical or sequential orderings thereof, unless otherwise indicated or specified

It is to be understood that while the invention has been described above with reference to preferred embodiments thereof, it is not limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent changes and modifications made to the foregoing embodiments based on the substantive disclosure of the invention without departing from the scope thereof fall within this scope.

1. A method for analysis of IC testing anomalies based on deep learning, comprising steps of:
(S1) collecting test data at a data collection module, wherein the test data comprises historical test data and real-time test data;
(S2) performing format conversion and feature extraction on the historical test data at a first input layer and pre-processing on the real-time test data at a pre-processing sub-module;
(S3) by a neural network sub-module, developing a trained neural network through training the neural network by means of deep learning with the historical test data that have been subject to the feature extraction and inputting the pre-processed real-time test data to the trained neural network for computational processing for deriving early warning information about testing anomalies and solutions to testing anomalies that have occurred;
(S4) at a human-computer interaction module, receiving the early warning information about testing anomalies and the solutions to testing anomalies that have occurred and displaying early warnings against the testing anomalies and the solutions.

2. The method for analysis of IC testing anomalies of claim 1, wherein S3 comprises:
(S31) at a second input layer in the neural network sub-module, receiving the historical test data that have been subject to the feature extraction, transmitting the received data to a middle layer in the neural network sub-module, and receiving the pre-processed real-time test data from the pre-processing sub-module;
(S32) by the middle layer, developing the trained neural network through training the neural network by means of deep learning with the historical test data that have been subject to the feature extraction, inputting the pre-processed real-time test data to the trained neural network for computational processing for deriving, in an event of anomalous testing, early warning information about testing anomalies and solutions to testing anomalies that have occurred, and transmitting the early warning information and the solutions to an output layer in the neural network sub-module; and
(S33) at the output layer, receiving the early warning information about testing anomalies and the solutions to testing anomalies that have occurred output from the middle layer and transmitting the early warning information and the solutions to the human-computer interaction module.

3. The method for analysis of IC testing anomalies of claim 2, wherein
an output data y1 of the middle layer obtained from learning by the neural network satisfy a following formula:
$$\text{y} 1 = \text{F} \left(\text{x} , \left\{{W}_{i}\right\}\right) ,$$
where x represents the historical test data input to the middle layer and Wᵢ denotes an i-th layer in the network.

4. The method for analysis of IC testing anomalies of claim 3, wherein
the output y1 of the middle layer obtained from learning by the neural network serving as a two-layer network is
$$\text{y} 1 = \text{σ} \left({\text{W}}_{2} \text{σ} \left({\text{W}}_{1} \text{x}\right)\right) ,$$
where σ is a nonlinear activation function.

5. The method for analysis of IC testing anomalies of claim 2, wherein
through the training by deep learning in the middle layer, a cross-entropy loss function corresponding to a minimized error is
$${\text{L}}_{log} \left(\text{y} , \text{p}\right) = - \left(\text{y} log \left(\text{p}\right) + \left(1 \text{-y}\right) log \left(1 \text{-p}\right)\right)$$
where y is a classification label having a value of 0 or 1, p is a probability of normal testing, and 1-p is a probability of anomalous testing.

6. The method for analysis of IC testing anomalies of claim 1, wherein the solutions comprise: how to achieve testing optimization; reminders for calibration or maintenance of testers, test probe cards and test fixtures; and automatic identification of testing anomalies that have occurred.

7. The method for analysis of IC testing anomalies of claim 1, wherein the feature extraction comprises classification of each type of neurons as normal or anomalous.

8. A system for analysis of IC testing anomalies based on deep learning, for implementing the method for analysis of IC testing anomalies as defined in claim 1, comprising:
a data collection module, configured to collect test data, wherein the test data comprise historical test data and real-time test data;
a first input layer, configured to perform format conversion and feature extraction on the historical test data;
a pre-processing sub-module, configured to pre-process the real-time test data;
a neural network sub-module, configured to develop a trained neural network through training the neural network by means of deep learning with the historical test data that have been subject to the feature extraction and input the pre-processed real-time test data to the trained neural network for computational processing for deriving early warning information about testing anomalies and solutions to testing anomalies that have occurred; and
a human-computer interaction module, configured to receive the early warning information about testing anomalies and the solutions to testing anomalies that have occurred and displaying early warnings against the testing anomalies and the solutions.

9. The system for analysis of IC testing anomalies of claim 8, wherein the test data comprise testing equipment data, testing hardware data, test yield data, test result data, test process data and test time data.

10. The system for analysis of IC testing anomalies of claim 8, wherein the neural network sub-module comprises:
a second input layer, configured to receive the historical test data that have been processed by the first input layer and the real-time test data that have been pre-processed by the pre-processing sub-module and transmit the test data to the middle layer;
a middle layer, configured to develop the trained neural network through training the neural network by means of deep learning with the historical test data, input the pre-processed real-time test data to the trained neural network for computational processing for deriving, in an event of anomalous testing, early warning information about testing anomalies and solutions to testing anomalies that have occurred, and transmit the early warning information about testing anomalies and the solutions to testing anomalies that have occurred to an output layer; and
the output layer, configured to transmit the early warning information about testing anomalies and the solutions to testing anomalies that have occurred to the human-computer interaction module.

11. The method for analysis of IC testing anomalies of claim 10, wherein
an output data y1 of the middle layer obtained from learning by the neural network satisfy a following formula:
$$\text{y} 1 = \text{F} \left(\text{x} , \left\{{W}_{i}\right\}\right) ,$$
where x represents the historical test data input to the middle layer and Wᵢ denotes an i-th layer in the network.

12. The method for analysis of IC testing anomalies of claim 11, wherein
the output y1 of the middle layer obtained from learning by the neural network serving as a two-layer network is
$$\text{y} 1 = \text{σ} \left({\text{W}}_{2} \text{σ} \left({\text{W}}_{1} \text{x}\right)\right) ,$$
where σ is a nonlinear activation function.

13. The method for analysis of IC testing anomalies of claim 10, wherein
through the training by deep learning in the middle layer, a cross-entropy loss function corresponding to a minimized error is
$$\text{Llog} \left(\text{y, p}\right) \text{=-} \left(\text{y log} \left(\text{p}\right) \text{+} \left(\text{1-y}\right) \text{log} \left(\text{1-p}\right)\right)$$
where y is a classification label having a value of 0 or 1, p is a probability of normal testing, and 1-p is a probability of anomalous testing.

14. The method for analysis of IC testing anomalies of claim 8, wherein the solutions comprise: how to achieve testing optimization; reminders for calibration or maintenance of testers, test probe cards and test fixtures; and automatic identification of testing anomalies that have occurred.

15. The method for analysis of IC testing anomalies of claim 8, wherein the feature extraction comprises classification of each type of neurons as normal or anomalous.
